(19) United States
(12) Patent Application Publication
(10) Pub. No.: US 2025/0081637 A1
(43) Pub. Date: Mar. 6, 2025

(54) IMAGE SENSING DEVICE

(71) Applicant: SK hynix Inc., Icheon-si (KR)

(72) Inventor: Jong Hwan SHIN, Icheon-si (KR)

(21) Appl. No.: 18/651,275

(22) Filed: Apr. 30, 2024

(30) Foreign Application Priority Data
Sep. 5, 2023 (KR) 10-2023-0117994

(51) Int. Cl. H01L 27/146

(52) U.S. Cl. CPC H10F 39/802; H10F 39/807

(57) ABSTRACT

An image sensing device includes a semiconductor substrate, a first pixel region, and a second gate. The semiconductor substrate includes a first pixel region configured to include at least one first photoelectric conversion region and at least one first floating diffusion region, a second pixel region located adjacent to the first pixel region in a first direction and configured to include at least one second photoelectric conversion region and at least one second floating diffusion region, and a first inter-pixel isolation structure disposed between the first pixel region and the second pixel region. The first gate disposed over the semiconductor substrate extends to overlap the first pixel region, the first inter-pixel isolation structure, and the second pixel region. The second gate disposed at one side of the first gate on the semiconductor substrate extends to overlap the first pixel region, the first inter-pixel isolation structure, and the second pixel region.

### CROSS-REFERENCE TO RELATED APPLICATION

This patent document claims the priority and benefits of Korean patent application No. 10-2023-0117994, filed on Sep. 5, 2023, which is incorporated by reference in its entirety as part of the disclosure of this patent document.

### TECHNICAL FIELD

The technology and implementations disclosed in this patent document generally relate to an image sensing device.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

The CCD image sensing device may be driven more easily than the CCD sensing device. The CMOS image sensing device enables conventional circuits to be integrated into a single chip, such that the CMOS image sensing device can be easily fabricated as a small-sized product, and has a higher degree of integration and very lower power consumption. In addition, the CMOS image sensing device is compatible with CMOS fabrication technology, resulting in reduction in production costs. In recent times, the CMOS image sensing devices have been intensively researched and rapidly come into widespread use.

### SUMMARY

Various embodiments of the disclosed technology relate to an image sensing device capable of improving operation characteristics of pixel transistors.

In accordance with an embodiment of the disclosed technology, an image sensing device may include a semiconductor substrate, a first pixel region, and a second gate. The semiconductor substrate may include a first pixel region configured to include at least one first photoelectric conversion region that converts incident light into photocharge and at least one first floating diffusion region configured to store the photocharge generated by the at least one first photoelectric conversion region, a second pixel region located adjacent to the first pixel region in a first direction, and configured to include at least one second photoelectric conversion region that converts incident light into photocharge and at least one second floating diffusion region that stores the photocharge generated by the at least one second photoelectric conversion region, and a first inter-pixel isolation structure disposed between the first pixel region and the second pixel region. The first gate may be disposed over the semiconductor substrate, and may extend to overlap the first pixel region, the first inter-pixel isolation structure, and the second pixel region. The second gate may be disposed at one side of the first gate on the semiconductor substrate, and may extend to overlap the first pixel region, the first inter-pixel isolation structure, and the second pixel region.

In accordance with another embodiment of the disclosed technology, an image sensing device may include a unit pixel group including a plurality of unit pixels that are disposed adjacent to each other in a first direction and a second direction perpendicular to the first direction, each unit pixel including at least one photoelectric conversion region that generates photocharge through conversion of incident light and at least one floating diffusion region that stores the photocharge generated by the at least one photoelectric conversion region. The unit pixel group may include a central portion, a left portion located at one side of the central portion, and a right portion located at another side opposite to the one side of the central portion. Each of the left portion and the right portion may include a plurality of first gates extending in a first direction to cross a plurality of unit pixels that is adjacent to each other in the first direction, and the central portion may include a plurality of second gates having an island shape and isolated from each other.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a structure of a unit pixel group shown in FIG. 1 based on some implementations of the disclosed technology.

FIG. 3A is a cross-sectional view illustrating an example of a unit pixel group taken along the line X1-X1′ shown in FIG. 2 based on some implementations of the disclosed technology.

FIG. 3B is a cross-sectional view illustrating an example of the unit pixel group taken along the line X2-X2′ shown in FIG. 2 based on some implementations of the disclosed technology.

FIG. 3C is a cross-sectional view illustrating an example of the unit pixel group taken along the line Y-Y′ shown in FIG. 2 based on some implementations of the disclosed technology.

FIG. 4 is a schematic diagram illustrating another example of a structure of the unit pixel group shown in FIG. 1 based on some implementations of the disclosed technology.

FIG. 5 is a schematic diagram illustrating still another example of a structure of the unit pixel group shown in FIG. 1 based on some implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device capable of improving operation characteristics of pixel transistors. The disclosed technology provides various implementations of the image sensing device that can improve not only operation characteristics thereof, but also random telegraph signal (RTS) characteristics thereof.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

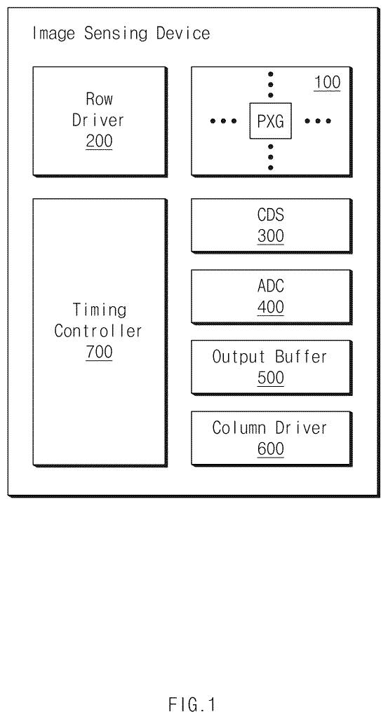

FIG. 1 is a block diagram illustrating an example of an image sensing device based on some implementations of the disclosed technology.

Referring to FIG. 1, the image sensing device may include a pixel array 100, a row driver 200, a correlated double sampler (CDS) 300, an analog-digital converter (ADC) 400, an output buffer 500, a column driver 600 and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light, and a phase detection pixel that is structured to generate second electrical signals for calculating a phase difference between the images.

The pixel array 100 may include a plurality of unit pixel groups (PXGs) arranged in rows and columns. In one example, the plurality of unit pixels (PXs) can be arranged in a two dimensional (2D) pixel array including rows and columns. Each unit pixel group (PXG) may include a plurality of unit pixels, each of which generates an electrical signal (pixel signal) for photoelectrically converting incident light to generate an image signal corresponding to a target object to be captured. For example, each unit pixel group (PXG) may include four unit pixels arranged adjacent to each other in a (2×2) matrix structure. Each of the unit pixels may include a photoelectric conversion region configured to generate photocharges through photoelectric conversion of incident light, and pixel transistors configured to generate a pixel signal corresponding to the photocharges generated by the photoelectric conversion region. Each unit pixel may include a plurality of photoelectric conversion regions separated from each other.

The pixel array 100 may receive driving signals (for example, a row selection signal, a reset signal, a transmission (or transfer) signal, etc.) from the row driver 200. Upon receiving the driving signals, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700. In some implementations, the row driver 200 may select one or more pixel groups arranged in one or more rows of the pixel array 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 700. The image data received from the ADC 400 may be temporarily stored in the output buffer 500 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column. In some implementations, the timing controller 700 may include a logic control circuit, a phase lock loop (PLL) circuit, a timing control circuit, a communication interface circuit and others.

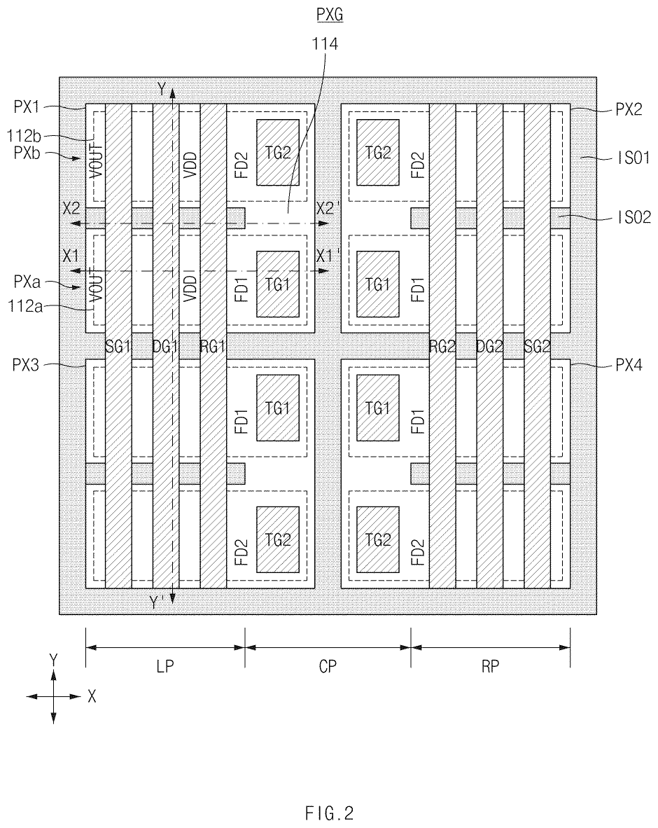

FIG. 2 is a schematic diagram illustrating an example of a structure of the unit pixel group (PXG) shown in FIG. 1 based on some implementations of the disclosed technology.

Referring to FIG. 2, each unit pixel group (PXG) may include a plurality of unit pixels (PX1˜PX4). The unit pixels (PX1˜PX4) may be arranged adjacent to each other in a first direction (e.g., a Y-axis direction) and a second direction (e.g., an X-axis direction) perpendicular to the first direction. For example, each unit pixel group (PXG) may include four unit pixels (PX1˜PX4) arranged in a (2×2) matrix structure. The unit pixels (PX1˜PX4) may be formed to have a back side illumination (BSI) structure that receives incident light through a surface (e.g., a back surface) facing or opposite to a surface (e.g., a front surface) on which the drive elements (e.g., pixel transistors) are formed in a semiconductor substrate.

Each of the unit pixels (PX1˜PX4) may be physically isolated from adjacent unit pixels by an inter-pixel isolation structure ISO1. In addition, each of the unit pixels (PX1˜PX4) may be divided into two sub-unit pixels (PXa, PXb) by an inner-pixel isolation structure ISO2. However, the isolation structures (ISO1, ISO2) are not limited to the example structure shown in FIG. 2, and other implementations are also possible. In some implementations, it should be noted that some parts of the isolation structure may also be omitted as necessary.

The inner-pixel isolation structure ISO2 may be formed to extend in the second direction between the sub-unit pixels (PXa, PXb). At this time, both ends of the inner-pixel isolation structure ISO2 may not be in contact with the inter-pixel isolation structure ISO1, only one end of the inner-pixel isolation structure ISO2 may be in contact with the inter-pixel isolation structure ISO1, and the other end of the inner-pixel isolation structure ISO2 may be spaced apart from the inter-pixel isolation structure IOS1. A device isolation region 114 containing a high concentration of P-type impurities may be formed in the region that contacts the other end of the inner-pixel isolation structure ISO2 and extends in a direction away from the other end of the inner-pixel isolation structure ISO2. Thus, the device isolation region 114 is spaced apart from the inter-pixel isolation structures IOS1.

Each of the inter-pixel isolation structure ISO1 and the inner-pixel isolation structure ISO2 may include a trench-shaped isolation structure in which an insulation material is buried in a trench which is etched in the substrate. In some implementations, the trench-shaped isolation structure may include a deep trench isolation (DTI) structure or a structure formed by a combination of the DTI structure and a shallow trench isolation (STI) structure. For example, each inter-pixel isolation structure ISO1 and each inner-pixel isolation structure ISO2 may include a Front Deep Trench Isolation (FDTI) structure. Each inter-pixel isolation structure ISO1 and each inner-pixel isolation structure ISO2 may include the same insulation material.

Electrical connection between elements belonging to different unit pixels may be made through conductive lines (e.g., metal lines) formed over the substrate.

In the unit pixel group (PXG), the unit pixels (PX1˜PX4) may be identical in structure to each other. For example, the unit pixels located adjacent to each other in the first or second direction may be formed symmetrical to each other with respect to the inter-pixel isolation structure ISO1 between the corresponding unit pixels.

Each of the unit pixels (PX1˜PX4) may include a 2-photodiode (2PD) structure including two photoelectric conversion regions (112a, 112b). Each of the unit pixels (PX1˜PX4) may include two sub-unit pixels (PXa, PXb), and each of the sub-unit pixels (PXa, PXb) may include a photoelectric conversion region, a floating diffusion region, and a transfer gate.

For example, the sub-unit pixel (PXa) may include a photoelectric conversion region 112a, a floating diffusion region FD1, and a transfer gate TG1, and the sub-unit pixel (PXb) may include a photoelectric conversion region 112b, a floating diffusion region FD2, and a transfer gate TG2. The transfer gate TG1 may transmit photocharges generated by the photoelectric conversion region 112a to the floating diffusion region FD1 based on the transfer signal. The transfer gate TG2 may transmit photocharges generated by the photoelectric conversion region 112b to the floating diffusion region FD2 based on the transfer signal.

In addition, each of the unit pixels (PX1˜PX4) may include a reset transistor, a source follower transistor, and a selection transistor. The reset transistor may include reset gates (RG1, RG2). The reset gates (RG1, RG2) may be disposed between a power-supply voltage (VDD) and the floating diffusion regions (FD1, FD2), and may reset the floating diffusion regions (FD1, FD2) to the power-supply voltage (VDD) based on a reset signal. The source follower transistor may include drive gates (DG1, DG2) connected to the floating diffusion regions (FD1, FD2). The source follower transistor may generate a pixel signal corresponding to the magnitude of voltage generated by the floating diffusion regions (FD1, FD2), and may output the pixel signal to the selection transistor. The selection transistor may be coupled in series to the source follower transistor, and may include selection gates (SG1, SG2). Each of the selection gates (SG1, SG2) may output a pixel signal to an output terminal (VOUT) based on a row selection signal.

In each unit pixel group (PXG), each of the selection gates (SG1, SG2), each of the drive gates (DG1, DG2), and each of reset gates (RG1, RG2) may be formed not to be isolated from each other per unit pixel. In some implementations, gates having the same characteristics in the adjacent unit pixels may be integrally connected to each other to form a single bar shape crossing the corresponding unit pixels. In some implementations, the gates having the same characteristics in the adjacent unit pixels can be integrally formed to have a single bar shape that completely crosses the corresponding unit pixels.

For example, the unit pixel group (PXG) may include a central portion (CP), a left portion (LP) located at one side (e.g., a left side) of the central portion (CP), and a right portion (RP) located at one side (e.g., a right side) opposite to the central portion (CP).

Some gates (SG1, DG1, RG1) from among the gates (SG1, SG2, DG1, DG2, RG1, RG2) of the pixel transistors may be arranged parallel to each other at the left side (LP) of the unit pixel group (PXG), and may extend long to continuously cross the unit pixels (PX1, PX3) adjacent to each other in the first direction. For example, as shown in FIG. 2, those gates (SG1, DG1, RG1) may overlap the unit pixels (PX1 and PX3) that are adjacent to each other in the first direction. Each of the gates (SG1, DG1, RG1) may be formed in a bar shape that overlaps four photoelectric conversion regions (112a, 112b) of the unit pixels (PX1, PX3), the inner-pixel isolation structures (ISO2) disposed between the photoelectric conversion regions (112a, 112b), and the inter-pixel isolation structure (ISO1) disposed between the unit pixels (PX1, PX3).

In some implementations, the remaining gates (SG2, DG2, RG2) from among the gates (SG1, SG2, DG1, DG2, RG1, RG2) of the pixel transistors may be arranged parallel to each other at the right side (RP) of the unit pixel group (PXG), and may extend long to sequentially cross the unit pixels (PX2, PX4) adjacent to each other in the first direction. For example, those gates (SG2, DG2, RG2) may overlap the unit pixels (PX2 and PX4) that are adjacent to each other in the first direction. Each of the gates (SG2, DG2, RG2) may be formed in a bar shape that overlaps four photoelectric conversion regions (112a, 112b) of the unit pixels (PX2, PX4), the inner-pixel isolation structures (ISO2) disposed between the photoelectric conversion regions (112a, 112b), and the inter-pixel isolation structure (ISO1) disposed between the unit pixels (PX2, PX4).

The gates (SG1, DG1, RG1) of the left portion (LP) and the gates (SG2, DG2, RG2) of the right portion (RP) may be arranged symmetrical to each other with respect to the central portion (CP). The gate electrodes (SG1, SG2, DG1, DG2, RG1, RG2) may be formed to have the same width, or may also be formed to have different widths.

Among the gates (SG1, DG1, RG1) of the left portion (LP) and the gates (SG2, DG2, RG2) of the right portion (RP), some gates having the same characteristics may be electrically connected to each other through conductive lines (e.g., metal lines).

The gates (e.g., transfer gates) TG1 and TG2 of the transfer transistor may be located at the central portion (CP) of the unit pixel group (PXG). Each of the transfer gates (TG1, TG2) may be formed in an island shape that is isolated for each sub-unit pixel (PXa, PXb) when viewed in a plane, and the transfer gates (TG1, TG2) may be arranged as two columns in the first direction.

As described above, each of the gates (SG1, DG1, RG1) of the pixel transistors may be formed as a bar shape in the left portion (LP) of the unit pixel group (PXG), and each of the gates (SG2, DG2, SG2) of the pixel transistors may be formed as a bar shape in the right portion (RP) of the unit pixel group (PXG). Specifically, the gates (SG1, DG1, RG1) in the left portion (LP) of the unit pixel group (PXG) may be arranged symmetrical to the gates (SG2, DG2, SG2) in the right portion (RP) of the unit pixel group (PXG). As a result, the size of the corresponding pixel transistors within the unit pixel group (PXG) can be maximized. In particular, as the size of the source follower transistor increases, random telegraph signal (RTS) characteristics of the image sensing device can be improved. In this way, the image sensing device according to the present embodiment can minimize the size of pixel transistors, such that operation characteristics (especially, RTS characteristics) of the image sensing device can be improved.

In the sub-unit pixels (PXa, PXb), floating diffusion regions (FD1, FD2) may be formed in a region between the reset gates (RG1, RG2) and the transfer gates (TG1, TG2). For example, in the pixels PX1 and PX3, the floating diffusion region (FD1) may be formed between the rest gate (RG1) and the transfer gate (TG1) and the floating diffusion region (FD2) may be formed between the reset gate (RG1) and the transfer gate (TG2). For example, in the pixels PX2 and PX4, the floating diffusion region (FD1) may be formed between the reset gate (RG2) and the transfer gate (TG1) and the floating diffusion region (FD2) may be formed between the reset gate (RG2) and the transfer gate (TG2).

A region (e.g., a source/drain region) between each of the reset gates (RG1, RG2) and each of the drive gates (DG1, DG2) may be connected to the power-supply voltage (VDD), and one region (e.g., a source/drain region) of each of the selection gates (SG1, SG2) may be connected to the output terminal (VOUT) through which the pixel signal is output.

In each unit pixel (PX1˜PX4), a device isolation region 114 may be formed between the transfer gates (TG1, TG2). The device isolation region 114 may include a junction isolation structure in which P-type impurities are implanted in an upper region of the substrate. Alternatively, the device isolation region 114 may include a shallow trench isolation (STI) structure formed to have a smaller depth than the inner-pixel isolation structure ISO2.

Although FIG. 2 illustrates an example case in which the sub-unit pixels (PXa, PXb) are arranged symmetrical to each other in the first direction within one unit pixel (PX) for convenience of description, other implementations are also possible, and it should be noted that the sub-unit pixels (PXa, PXb) may also be arranged symmetrical to each other in the second direction while being spaced apart from each other.

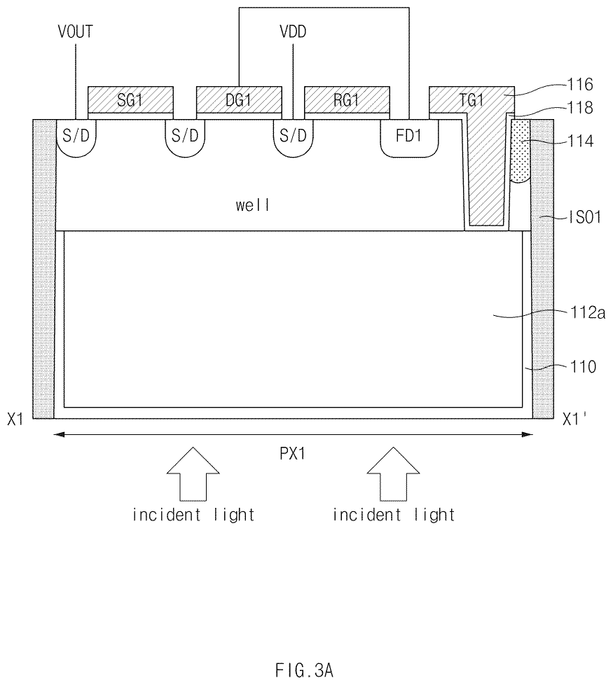

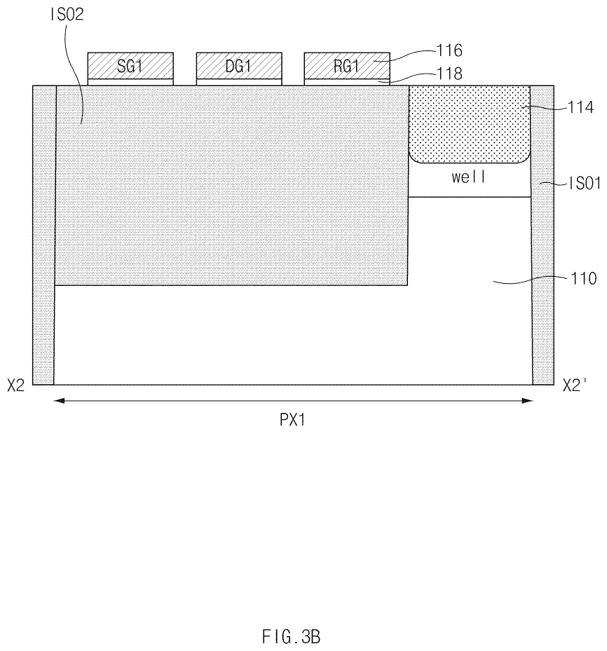

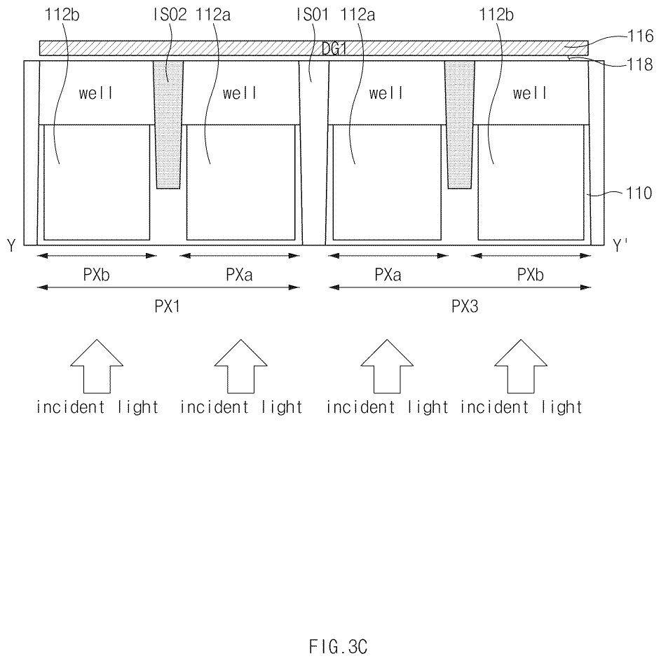

FIG. 3A is a cross-sectional view illustrating an example of a unit pixel group taken along the line X1-X1′ shown in FIG. 2 based on some implementations of the disclosed technology. FIG. 3B is a cross-sectional view illustrating an example of the unit pixel group taken along the line X2-X2′ shown in FIG. 2 based on some implementations of the disclosed technology. FIG. 3C is a cross-sectional view illustrating an example of the unit pixel group taken along the line Y-Y′ shown in FIG. 2 based on some implementations of the disclosed technology.

Referring to FIGS. 3A to 3C, the substrate 110 may include a first surface (e.g., a back surface) and a second surface (e.g., a front surface) facing or opposite to the first surface. The substrate 110 may include a monocrystalline silicon substrate or an epitaxially grown monocrystalline silicon substrate.

In the substrate 110, pixel regions respectively corresponding to the unit pixels (PX1, PX3) may be physically isolated from each other by the inter-pixel isolation structure ISO1. The inter-pixel isolation structure ISO1 may include a deep trench isolation (DTI) structure, and may be formed to penetrate the substrate 110. The inter-pixel isolation structure ISO1 may include a front deep trench isolation (FDTI) structure in which an insulation material (e.g., silicon oxide or silicon nitride) is buried in a trench etched from the front surface toward the back surface of the substrate 110.

In each pixel region, the photoelectric conversion regions (112a, 112b) of the sub-unit pixels (PXa, PXb) may be physically isolated from each other by the inner-pixel isolation structures (ISO2). Each of the inner-pixel isolation structures (ISO2) may include a DTI or STI structure formed to have a smaller depth than the inter-pixel isolation structure (ISO1). Each of the inner-pixel isolation structures (ISO2) may be formed to a predetermined depth such that the inner-pixel isolation structure (ISO2) does not penetrate the substrate 110.

In each pixel region, a device isolation region 114 may be formed in a region in which the inner-pixel isolation structure (ISO2) is not formed and in a boundary region between the sub-unit pixels (PXa, PXb) (e.g., a region between the inter-pixel isolation structure ISO1 and the inner-pixel isolation structure ISO2). In addition, a device isolation region 114 may be formed between the transfer gate (TG1) and the inter-pixel isolation structure (ISO1). The device isolation region 114 may include a junction-type isolation structure in which impurities are implanted into the upper region of the substrate 110. For example, the device isolation region 114 may include an impurity region that contacts a top surface of the substrate 110 and is implanted with P-type impurities to a predetermined depth from the top surface of the substrate 110. The device isolation region 114 may include a higher concentration of P-type impurities than the well region.

The photoelectric conversion region 112a may be formed in the lower region of the substrate 110 within the sub-unit pixel (PXa) region, and the photoelectric conversion region 112b may be formed in the lower region of the substrate 110 within the sub-unit pixel (PXb) region. In order to increase light reception (Rx) efficiency, the photoelectric conversion regions (112a, 112b) may be arranged to occupy as large a region as possible in the lower region of the substrate 110 within the corresponding sub-unit pixel (PXa, PXb). The photoelectric conversion regions (112a, 112b) may include N-type impurities. A well region containing P-type impurities may be formed over the photoelectric conversion regions (112a, 112b) within the substrate of the sub-unit pixels (PXa, PXb).

Gates (TG1, SG1, DG1, RG1) of pixel transistors may be formed over the second surface of the substrate 110. That is, each of the unit pixels (PX1, PX3) may include a back side illumination (BSI) structure in which the drive elements (TG1, SG1, DG1, RG1) are formed on the side (e.g., a second surface) opposite to the side (e.g., a first surface) upon which light is incident from the outside.

The gates (TG1, SG1, DG1, RG1) of the pixel transistors may include a conductive material 116 and a gate insulation layer 118 disposed between the conductive material 116 and the substrate 110. The conductive material 116 may include, for example, metal or doped polysilicon. The gate insulation layer 118 may include an oxide layer formed by oxidation of the surface of the substrate 110.

The transfer gate (TG1) may transmit photocharges generated by the photoelectric conversion region 112a to the floating diffusion region (FD1) based on the transfer signal. The transfer gate (TG1) may include a recess gate formed in the trench etched in the substrate 110 to form a vertical channel in the well region, and a planar gate formed on the second surface of the substrate 110 to form a horizontal channel in the well region.

In the upper region of the substrate 110, the floating diffusion region FD1 may be formed between the reset gate RG1 and the transfer gate TG1. The floating diffusion region FD1 may include N-type impurities. The reset gate RG1 may connect the floating diffusion region FD1 to the power-supply voltage (VDD) based on the reset signal, and may reset the floating diffusion region FD1 to the power-supply voltage (VDD).

Each source/drain region (S/D) between the reset gate (RG1) and the drive gate (DG1) may be connected to the power-supply voltage (VDD), and one source/drain region (S/D) located at one side of the selection gate (SG1) may be connected to the output terminal (VOUT) through which the pixel signal is output. The source/drain regions (S/D) may include N-type impurities.

Although only the cross-sectional structure of the sub-unit pixel (PXa) is shown in FIG. 3A for convenience of description, the sub-unit pixel (PXb) may also be formed to have the same structure as the sub-unit pixel (PXa).

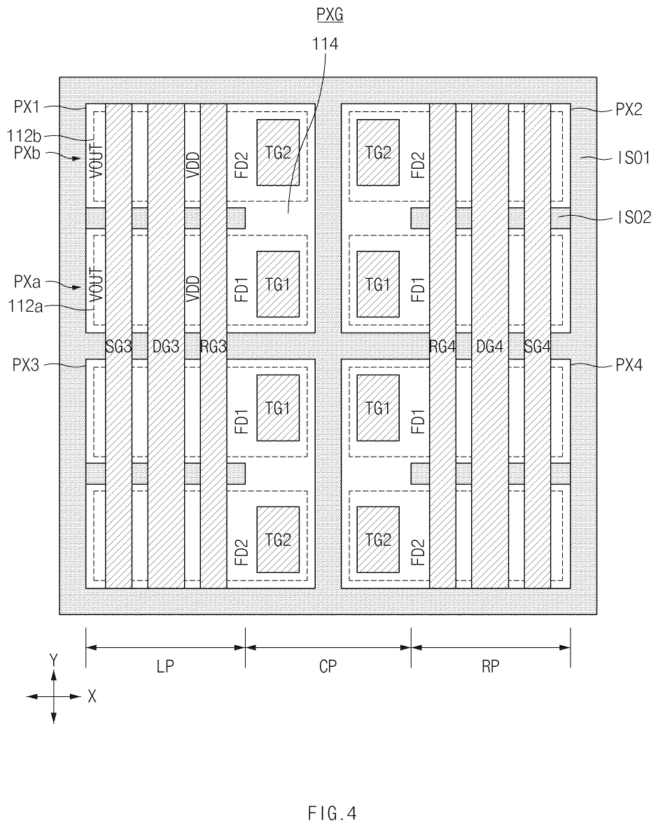

FIG. 4 is a schematic diagram illustrating another example of a structure of the unit pixel group (PXG) shown in FIG. 1 based on some implementations of the disclosed technology.

Referring to FIG. 4, in the left portion (LP) and the right portion (RP) of the unit pixel group (PXG), each of the drive gates (DG3, DG4) may be formed to have a larger width than each of the selection gates (SG3, SG4) or each of the reset gates (RG3, RG4). For example, compared to FIG. 2 described above, each of the drive gates (DG3, DG4) shown in FIG. 4 may be formed to have a larger width than each of the drive gates (DG1, DG2) shown in FIG. 2. As the width of each of the drive gates (DG3, DG4) increases, each of the selection gates (SG3, SG4) of FIG. 4 may be formed to have a smaller width than each of the selection gates (SG1, SG3) of FIG. 2, and each of the reset gates (RG3, RG4) of FIG. 4 may be formed to have a smaller width than each of the reset gates (RG1, RG1) of FIG. 2.

As described above, the random telegraph signal (RTS) characteristics can be improved as the size of the source follower transistor becomes larger, so that each of the drive gates (DG3, DG4) may be formed to have a larger width, resulting in improvement in RTS characteristics.

Compared to the embodiment of FIG. 2, although the gates (SG3, SG4, DG3, DG4, RG3, RG4) shown in FIG. 4 are different in width from the gates (SG1, SG2, DG1, DG2, RG1, RG2) of FIG. 2, the remaining components except for a difference in width between the gates of FIG. 4 and the gates of FIG. 2 are the same as those of FIG. 2, and as such redundant description thereof will herein be omitted for brevity.

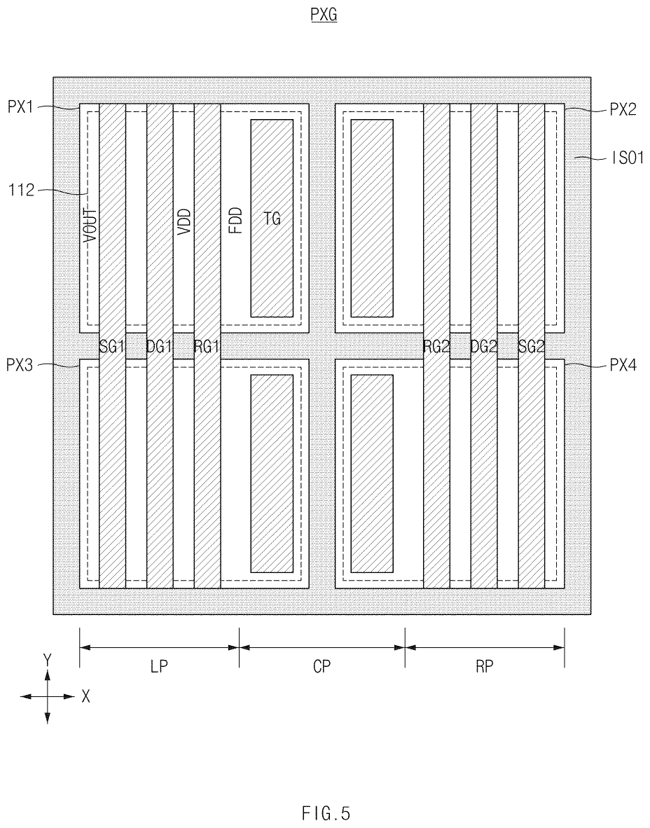

FIG. 5 is a schematic diagram illustrating still another example of a structure of the unit pixel group (PXG) shown in FIG. 1 based on some implementations of the disclosed technology.

Referring to FIG. 5, each unit pixel of the unit pixel group (PXG) may include a single photoelectric conversion region 112, a single floating diffusion region FD, and a single transfer gate TG.

Although the above-described embodiments of FIGS. 2 and 4 have disclosed examples of the 2PD structure in which each of the unit pixels (PX1˜PX4) of the unit pixel group (PXG) includes two photoelectric conversion regions (112a, 112b), other implementations are also possible. However, the structure of the above-described gates (SG1˜SG4, DG1˜DG4, and RG1˜RG4) can also be applied to the unit pixel group (PXG) including the unit pixels (PX1˜PX4) each including one photoelectric conversion region 112 and one transfer gate (TG), as shown in FIG. 5.

As is apparent from the above description, the image sensing device based on some implementations of the disclosed technology can improve operation characteristics thereof. In particular, the image sensing device can improve random telegraph signal (RTS) characteristics thereof.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a semiconductor substrate including:
a first pixel region configured to include at least one first photoelectric conversion region that converts incident light into photocharge and at least one first floating diffusion region configured to store the photocharge generated by the at least one first photoelectric conversion region,
a second pixel region located adjacent to the first pixel region in a first direction, and configured to include at least one second photoelectric conversion region that converts incident light into photocharge and at least one second floating diffusion region that stores the photocharge generated by the at least one second photoelectric conversion region, and
a first inter-pixel isolation structure disposed between the first pixel region and the second pixel region;
a first gate disposed over the semiconductor substrate and extending to overlap the first pixel region, the first inter-pixel isolation structure, and the second pixel region; and
a second gate disposed at one side of the first gate on the semiconductor substrate and extending to overlap the first pixel region, the first inter-pixel isolation structure, and the second pixel region.

2. The image sensing device according to claim 1, wherein:
each of the first gate and the second gate has a bar shape, and the first gate and the second gate are arranged parallel to each other.

3. The image sensing device according to claim 2, wherein:
the first gate and the second gate have a same width.

4. The image sensing device according to claim 2, wherein
the first gate and the second gate have different widths from each other.

5. The image sensing device according to claim 1, wherein the first gate includes:
a drive gate connected to the at least one first floating diffusion region and the at least one second floating diffusion region.

6. The image sensing device according to claim 1, wherein the second gate includes:
a reset gate disposed at one side of each of the first floating diffusion region and the second floating diffusion region, and configured to reset the first floating diffusion region and the second floating diffusion region based on a reset signal.

7. The image sensing device according to claim 1, further comprising:
a third gate disposed at an opposite side of the first gate, and configured to extend across the first pixel region, the first pixel isolation structure, and the second pixel region.

8. The image sensing device according to claim 7, wherein:
each of the first to third gates has a bar shape, and the first to third gates are arranged parallel to each other.

9. The image sensing device according to claim 8, wherein:
the first to third gates have a same width.

10. The image sensing device according to claim 8, wherein
the first to third gates have different widths from one another.

11. The image sensing device according to claim 1, wherein each of the first photoelectric conversion region and the second photoelectric conversion region includes:
a first sub-photoelectric conversion region; and
a second sub-photoelectric conversion region disposed at one side of the first sub-photoelectric conversion region in a direction in which the first and second gates are extended, and isolated from the first sub-photoelectric conversion region by an inner-pixel isolation structure.

12. The image sensing device according to claim 1, wherein the semiconductor substrate further includes:
a third pixel region disposed adjacent to the first pixel region in a second direction perpendicular to the first direction, and configured to include at least one third photoelectric conversion region that converts incident light into photocharge and at least one third floating diffusion region that stores the photocharge generated by the at least one third photoelectric conversion region;
a fourth pixel region disposed adjacent to the third pixel region in the first direction, and configured to include at least one fourth photoelectric conversion region that converts incident light into photocharge and at least one fourth floating diffusion region that stores the photocharge generated by the at least one fourth photoelectric conversion region; and
a second inter-pixel isolation structure disposed between the third pixel region and the fourth pixel region.

13. The image sensing device according to claim 12, further comprising:
a third gate disposed on the semiconductor substrate and extending in a bar shape to cross the third pixel region, the second inter-pixel isolation structure, and the fourth pixel region; and
a fourth gate disposed at one side of the third gate on the semiconductor substrate and extending in a bar shape to cross the third pixel region, the second inter-pixel isolation structure, and the fourth pixel region.

14. The image sensing device according to claim 13, further comprising:
at least one first transfer gate disposed in the first pixel region between the second gate and the fourth gate, and configured to transmit the photocharge generated by the at least one first photoelectric conversion region to the at least one first floating diffusion region based on a transfer signal;
at least one second transfer gate disposed in the second pixel region between the second gate and the fourth gate, and configured to transmit the photocharge generated by the at least one second photoelectric conversion region to the at least one second floating diffusion region based on a transfer signal;
at least one third transfer gate disposed in the third pixel region between the second gate and the fourth gate, and configured to transmit the photocharge generated by the at least one third photoelectric conversion region to the at least one third floating diffusion region based on a transfer signal; and
at least one fourth transfer gate disposed in the fourth pixel region between the second gate and the fourth gate, and configured to transmit the photocharge generated by the at least one fourth photoelectric conversion region to the at least one fourth floating diffusion region based on a transfer signal.

15. An image sensing device, comprising:
a unit pixel group including a plurality of unit pixels that are disposed adjacent to each other in a first direction and a second direction perpendicular to the first direction, each unit pixel including at least one photoelectric conversion region that generates photocharge through conversion of incident light and at least one floating diffusion region that stores the photocharge generated by the at least one photoelectric conversion region,
wherein the unit pixel group includes a central portion, a left portion located at one side of the central portion, and a right portion located at another side opposite to the one side of the central portion,
wherein
each of the left portion and the right portion includes a plurality of first gates extending in a first direction to cross a plurality of unit pixels that is adjacent to each other in the first direction, and
the central portion includes a plurality of second gates having an island shape and isolated from each other.

16. The image sensing device according to claim 15, wherein:
each of the first gates has a bar shape, and the first gates are arranged parallel to each other.

17. The image sensing device according to claim 15, wherein the first gates include:
a drive gate connected to the at least one floating diffusion region;
a reset gate disposed at one side of the drive gate and configured to reset the floating diffusion region based on a reset signal; and
a selection gate disposed at another side opposite to the one side of the drive gate and configured to output a pixel signal to an output terminal based on a row selection signal.

18. The image sensing device according to claim 17, wherein:
the drive gate, the reset gate, and the selection gate are extended to have a same width.

19. The image sensing device according to claim 17, wherein
the drive gate, the reset gate, and the selection gate have different widths from one another.

20. The image sensing device according to claim 15, wherein the second gates include:
a plurality of transfer gates configured to transmit the photocharge generated by the at least one photoelectric conversion region to the at least one floating diffusion region based on a transfer signal.
